(19) United States
(12) Patent Application Publication
(10) Pub. No.: US 2008/0315281 A1
(43) Pub. Date: Dec. 25, 2008

(54) Flash Memory Device and Method of Manufacturing the Same

(76) Inventor: Sung Kun PARK, Cheongju-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/144,423

(22) Filed: Jun. 23, 2008

(30) Foreign Application Priority Data
Jun. 25, 2007 (KR) 10-2007-0062112

(51) Int. Cl. H01L 29/00; H01L 21/3205

(52) U.S. Cl. 257/315; 438/593; 257/E29.001; 257/E21.294

(57) ABSTRACT

Disclosed are a flash memory device and a method of manufacturing the same. In the method of manufacturing the flash memory device, gate patterns of a cell area and a logic area are formed by sequentially depositing and patterning a first polysilicon layer, an ONO layer and a second polysilicon layer without separately performing a photolithography process for one of the gate patterns. A mask process for removing a dummy gate pattern in the logic area is performed to form transistors in the cell area and the logic area, so that the manufacturing process is simplified.

The present application claims priority under 35 U.S.C. 119 and 35 U.S.C. 365 to Korean Patent Application No. 10-2007-0062112 (filed on Jun. 25, 2007), which is hereby incorporated by reference in its entirety.

### BACKGROUND

A flash memory device is a non-volatile memory device, which can maintain information stored in a memory cell even if power is not supplied to the flash memory device and can electrically erase the information at a high speed while being mounted on a printed circuit board. The flash memory technology has been grown while variously modifying the cell structure. Recently, as semiconductor devices have tended toward highly integration and miniaturization, a process of manufacturing the flash memory device has been complicated and the process steps have been increased.

### SUMMARY

Embodiments of the invention relate to a flash memory device and a method of manufacturing the same.

A flash memory device according to various embodiments includes a first gate pattern and a second gate pattern on a semiconductor substrate and connected to each other; a first dummy insulating layer pattern covering the first gate pattern; a first dummy gate pattern covering the first dummy insulating layer pattern; and a dielectric layer covering the first dummy gate pattern and the second gate pattern and having a contact hole through which a portion of the second gate pattern is exposed.

A flash memory device according to other embodiments includes a gate stack including a floating gate pattern, an insulating layer pattern and a control gate pattern on a semiconductor substrate in a cell area; a first gate spacer covering a side of the gate stack; a first gate pattern and a second gate pattern connected to the first gate pattern on the semiconductor substrate in a logic region; a first dummy insulating layer pattern covering the first gate pattern; a first dummy gate pattern covering the first dummy insulating layer pattern; a second gate spacer that covers sides of the first gate pattern, the first dummy insulating layer pattern and the first dummy gate pattern; a third gate spacer connected to the second gate spacer and covering a side of the second gate pattern; and a dielectric layer having a contact hole through which a portion of the second gate pattern is exposed.

A method of manufacturing a flash memory device according to some embodiments includes the steps of sequentially stacking a first polysilicon layer, an insulating layer and a second polysilicon layer on a semiconductor substrate having a cell area and a logic area; patterning the first polysilicon layer, the insulating layer and the second polysilicon layer to form a first gate stack and a second gate stack in the cell area and the logic area, respectively; forming a photoresist pattern covering the first gate stack and a portion of the second gate stack; removing the second polysilicon layer of the second gate stack exposed by the photoresist pattern; removing the photoresist pattern and then forming a spacer at sides of the gate stack and the second gate stack; forming a dielectric layer covering the first gate stack and the second gate stack; and exposing a portion of the second gate stack by selectively etching the dielectric layer.

A method of manufacturing a flash memory device according to other embodiments includes the steps of sequentially stacking a first polysilicon layer, an insulating layer and a second polysilicon layer on a semiconductor substrate; patterning the first polysilicon layer, the insulating layer and the second polysilicon layer to form a first gate stack and a second gate stack, respectively: forming a first spacer and a second spacer that cover sides of the first gate stack and the second gate stack, respectively; forming a photoresist pattern covering the first gate stack and a portion of the second gate stack; removing the second polysilicon layer of the second gate stack exposed by the photoresist pattern; removing the photoresist pattern and forming a dielectric layer covering the first gate stack and the second gate stack; and exposing a portion of the second gate stack by selectively etching the dielectric layer.

According to embodiments of the invention, the manufacturing process for the flash memory device can be simplified and the manufacturing cost can be reduced, a defect rate of the device can be reduced and reliability of the device in a cell area can be improved, and electrical characteristics of the flash memory device can be improved.

### BRIEF DESCRIPTION OF THE DRAWINGS

FIG. 1 is a plan view representing a portion of a first exemplary flash memory device;

FIG. 2 is a sectional view representing the flash memory taken along line I-I′ of FIG. 1;

FIGS. 3 to 15 are sectional views sequentially showing a first exemplary process of manufacturing the flash memory device; and

FIGS. 16 to 21 are sectional views showing a second exemplary process of manufacturing a flash memory device.

### DETAILED DESCRIPTION OF THE EMBODIMENTS

A flash memory device and a method of manufacturing the same according to embodiments of the invention will be described in detail with reference to accompanying drawings. Although the preferred embodiments of the present invention have been disclosed for illustrative purposes, those skilled in the art will appreciate that various modifications, additions, deletions and substitutions are possible without departing from the scope and sprit of the invention as disclosed in the accompanying claims.

The terms “first” and” second” described below are used to distinguish members of a same or similar group from each other and to represent at least two members, not to define the members. Accordingly, if the terms “first” and “second” are mentioned, a plurality of members are provided, and the members can be selectively or alternatively used. The size (dimension) of elements shown in the drawings can be magnified for the purpose of clear explanation, and the real size of the elements may be different from the size of elements shown in drawings. In addition, the present invention may not include all the elements shown in the drawings and may not be limited thereto. The elements except for essential elements of the present invention can be omitted or added without limitation. In the following description, it will be understood that, when a layer (or film), a region, a pattern, or a structure is referred to as being “on” (or “above,” “over” or “upper”) or “under” (pr “below,” “down” or “lower”) another substrate, layer(or film), region, pad, or pattern, it can be directly on the other substrate, layer (or film), region, pad or pattern, or intervening layers may also be present. Furthermore, it will be understood that, when a layer (or film), a region, a pattern, a pad, or a structure is referred to as being “between” two layers (or films), regions, pads or patterns, it can be the only layer between the two layers (or films), regions, pads, or patterns or one or more intervening layers may also be present. Thus, the meaning should be determined by the context or technical idea of the disclosure.

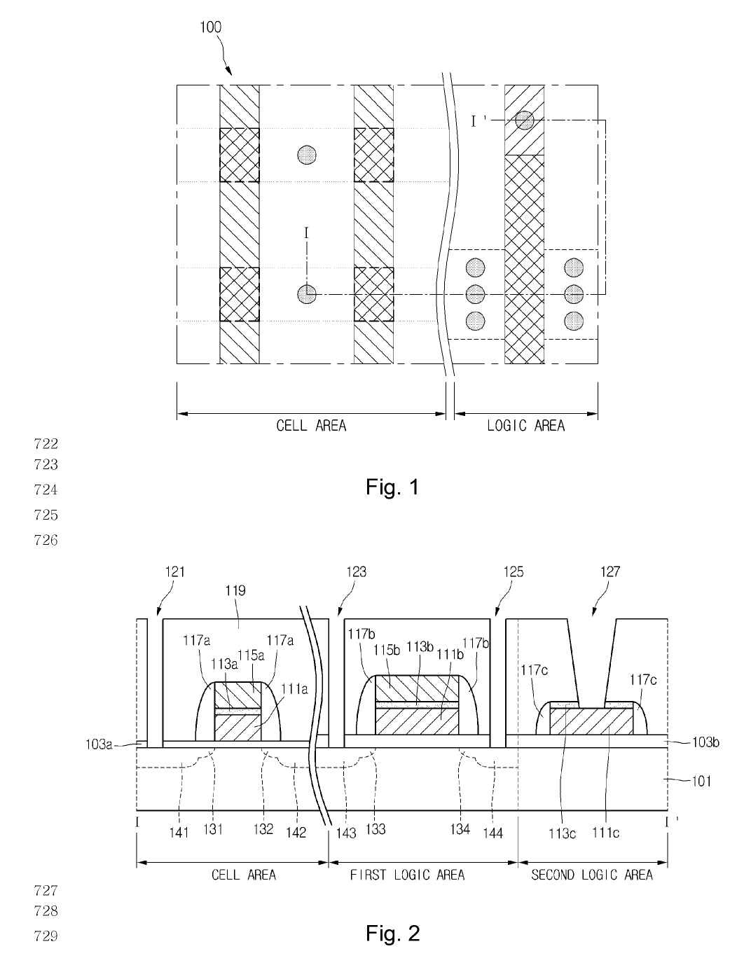

FIG. 1 is a plan view representing a portion of a first exemplary flash memory device. FIG. 2 is a sectional view representing the flash memory device taken along line I-I′ of FIG. 1. As shown in FIGS. 1 and 2, a flash memory device 100 includes a cell area and a logic area.

Transistors for storing information are formed in the cell area of the flash memory device 100. High voltage driving transistors and low voltage driving transistors for driving the transistors of the cell area are formed in the logic area of the flash memory device 100.

Hereinafter, the cell area of the flash memory device 100 will be described.

A first gate insulating layer 103a is formed on a semiconductor substrate 101. The gate insulating layer 103a is formed on the entire surface of the semiconductor substrate 101 or only on a gate electrode area. A floating gate pattern 111a is formed on the gate insulating layer 103a of the gate electrode area. An Oxide-Nitride-Oxide layer (hereinafter, referred to as “ONO” layer) pattern 113a is formed on the floating gate pattern 111a. A control gate pattern 115a is formed on the ONO pattern 113a. For example, the floating gate pattern 111a and the control gate pattern 115a may include polysilicon.

A first gate spacer 117a is formed at sides of a gate stack including the floating gate pattern 111a, the ONO pattern 113a and the control gate pattern 115a. The first gate spacer 117a covers a portion of the semiconductor substrate 101 on sides of the gate stack while covering the sides of the gate stack. The first gate spacer 117a may comprise silicon dioxide and/or silicon nitride.

The semiconductor substrate 101 has a source area 142 and a drain area 141 on opposite sides of the gate stack and the first gate spacer 117a. The source area 142 and the drain area 141 are formed by implanting or heavily doping first conductivity-type impurities into the semiconductor substrate 101 at a predetermined implantation energy. The first impurities may include a ‘p’ type impurity or ‘n’ type impurity. Lightly doped ion implantation areas 131 and 132 are formed on the semiconductor substrate 101 corresponding to a lower portion of (e.g., below) the first gate spacer 117a.

An interlayer dielectric layer 119 is formed on the semiconductor substrate 101 on which the gate stack is formed. The interlayer dielectric layer 119 includes a first contact hole 121 through which a portion of the drain area 141 of the semiconductor substrate 101 is exposed. The interlayer dielectric layer 119 may comprise a silicon oxide (e.g., silicon dioxide, which may be doped with fluorine or one or more of boron and phosphorous), a silicon nitride layer above and/or below the silicon oxide, and when the silicon oxide layer comprises a fluorine-doped silicon oxide, an undoped silicon dioxide layer above and/or below the fluorine-doped silicon oxide. The first gate insulating layer 103a also has the first contact hole 121 therein.

Hereinafter, a first logic area and a second logic area of the flash memory device 100 will be described.

The first logic area is formed with logic transistors and the second logic area is formed with a gate contact electrode, which applies a gate voltage to the logic transistors. A second gate insulating layer 103b is formed on the semiconductor substrate 101. The second gate insulating layer 103b may be formed on the entire surface of the semiconductor substrate 101 or only on a gate electrode area.

A first gate pattern 111b and a second gate pattern 111c are formed in the gate electrode areas on the second insulating layer 103b. The first gate pattern 111b and the second gate pattern 111c are substantially connected to each other in the form of a single pattern. In an extreme view, the first gate pattern 111b and the second gate pattern 111c are parts or portions of the same gate structure (see FIG. 1). The first gate pattern 111b and the second gate pattern 111c have a thickness and material identical to those of the floating gate pattern 111a formed in the cell area. The width of the first and second gate patterns 111b and 111c may be different from that of the floating gate pattern 111a. The width of the gate stack of the cell area is smaller than the width of the first gate pattern 111b and the second gate pattern 111c of the logic area.

A first dummy ONO pattern 113b and a first dummy gate pattern 115b are sequentially on the first gate pattern 111b. The first dummy ONO pattern 113b and the first dummy gate pattern 115b have a thickness and a material identical to those of the ONO pattern 113a and the control gate pattern 115a of the cell area, respectively.

A second spacer 117b is formed at sides of a gate stack including the first gate pattern 111b, the first dummy ONO pattern 113b and the first dummy gate pattern 115b. The second gate spacer 117b covers a portion of the semiconductor substrate 101 while covering sides of the first gate pattern 111b, the first dummy ONO pattern 113b and the first dummy gate pattern 115b. The second gate spacer 117b may comprise the same material(s) as first gate spacer 117a.

Meanwhile, a second dummy ONO pattern 113c is formed on the second gate pattern 111c. The second dummy ONO pattern 113c is connected to the first dummy ONO pattern 113b in the form of a single pattern.

A third gate spacer 117c is formed at sides of the second gate pattern 111c and the second dummy ONO pattern 113c. The third spacer 117c covers a portion of the semiconductor substrate 101 while covering the sides of the second gate pattern 111c and the second dummy ONO pattern 113c. The third gate spacer 117c has a height lower than the height of the first and second gate spacers 117a and 117b, but may comprise the same material(s) as the first gate spacer 117a.

The semiconductor substrate 101 has a source area 143 and a drain area 144 at opposite sides of the first gate pattern 111b. The source area 143 and the drain area 144 can be formed by implanting or highly doping first conductivity-type impurities into the semiconductor substrate 101 at a predetermined implantation energy. The first impurities may include a ‘p’ type impurity or an ‘n’ type impurity.

Lightly doped ion implantation areas 133 and 134 are formed on the semiconductor substrate 101 at a lower portion of the second gate spacer 117b.

The interlayer dielectric layer 119 is formed on the entire surface of the semiconductor substrate 101 on which the first gate pattern 111b and the second gate pattern 111c. The interlayer dielectric layer 119 has a second contact hole 123 and a third contact hole 125 through which the source area 143 and the drain area 144 formed at opposite sides of the first gate pattern 111b are partially exposed, respectively. The interlayer dielectric layer 119 of the second logic area has a fourth contact hole 127 through which a portion of an upper part of the second gate pattern 111c is exposed. The second dummy ONO pattern 113c below the interlayer dielectric layer 119 also has the fourth contact hole 127 therein. The second gate insulating layer 103b below the interlayer dielectric layer 119 has the second contact hole 123 and the third contact hole 125.

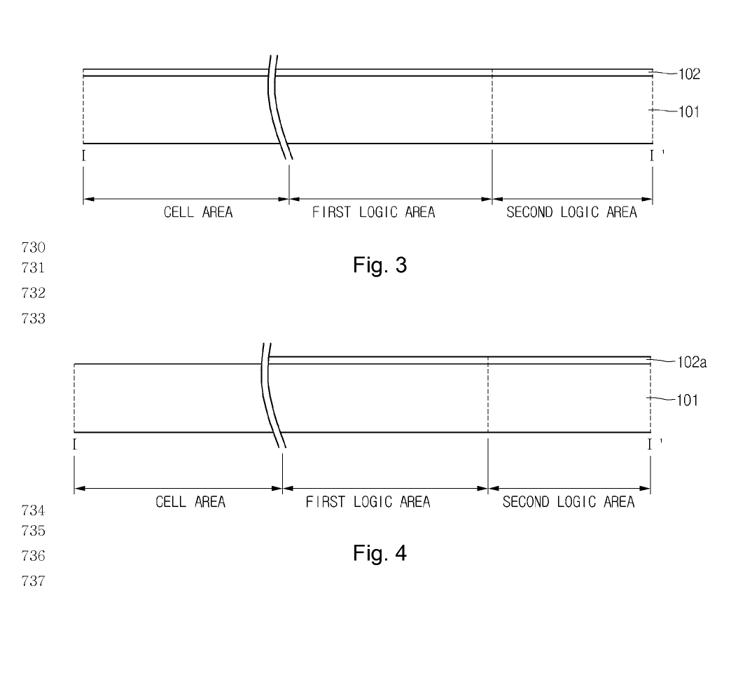

FIGS. 3 to 15 are sectional views sequentially showing a process of manufacturing the flash memory device according to the first embodiment.

As shown in FIG. 3, a first oxide layer 102 is formed on the entire surface of the semiconductor substrate 101 having the cell area, the first logic area and the second logic area. The first oxide layer 102 can be formed by thermally oxidizing the semiconductor substrate 101. The thermal oxidation process is performed through an RTP (Rapid Thermal Processing) in a temperature range of 800 to 900° C.□. The first oxidation layer 102 is formed by heat-treating the semiconductor substrate 101 in an oxygen atmosphere during the thermal oxidation process.

As shown in FIG. 4, the first oxide layer 102 is patterned such that an oxide layer pattern 102a is formed on the semiconductor substrate 101 in the first and second logic areas.

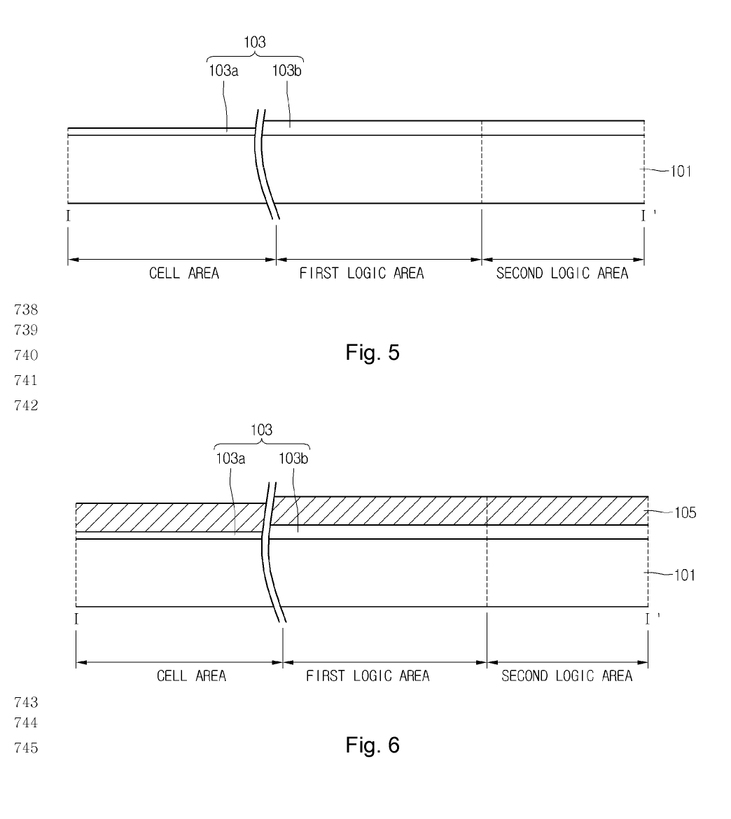

As shown in FIG. 5, the entire surface of the semiconductor substrate 101 having the oxide layer pattern 102a is etched to form a gate insulating layer 103 having a step difference. The first gate insulating layer 103a is formed on the semiconductor substrate 101 in the cell area. The second gate insulating layer 103b is formed in the semiconductor substrate 101 of the first and second logic areas. For example, the first gate insulating layer 103a has a thickness of 80 to 100 Å, and the second gate insulating layer 103b has a thickness of 130 to 170 Å.

As shown in FIG. 6, polysilicon is deposited on the entire surface of the semiconductor substrate 101 having the first and second gate insulating layers 103a and 103b to form a first polysilicon layer 105. The first polysilicon layer 105 is formed in the cell area and the logic area.

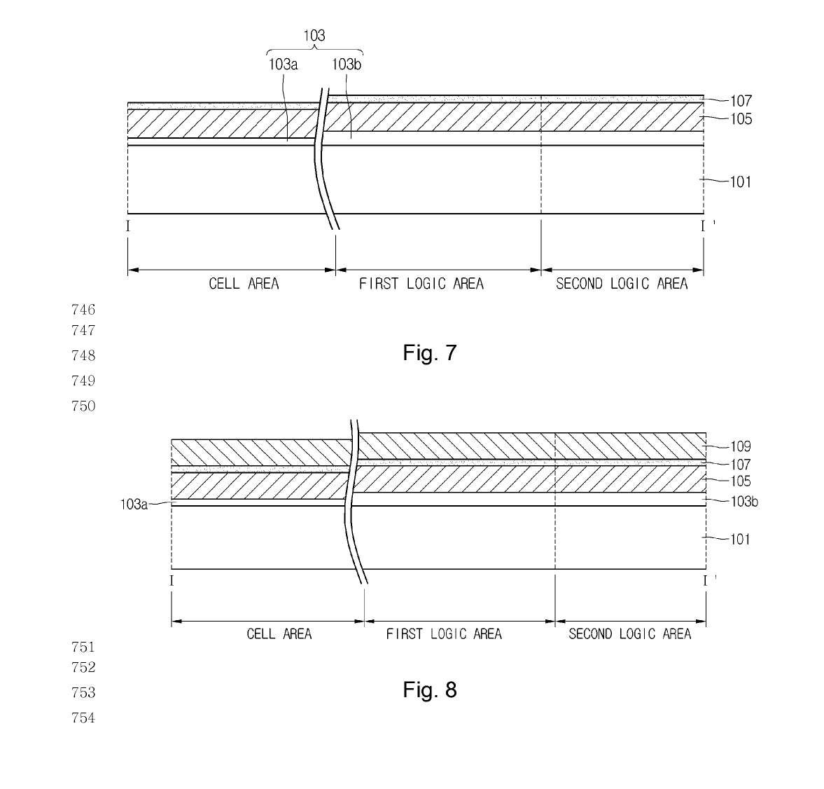

As shown in FIG. 7, an oxide layer, a nitride layer and an oxide layer are sequentially deposited on the first polysilicon layer 105 to form an ONO layer 107.

As shown in FIG. 8, polysilicon is deposited on the ONO layer 107 to form a second polysilicon layer 109. The ONO layer 107 and the second polysilicon layer 109 are formed in the cell area and the logic area.

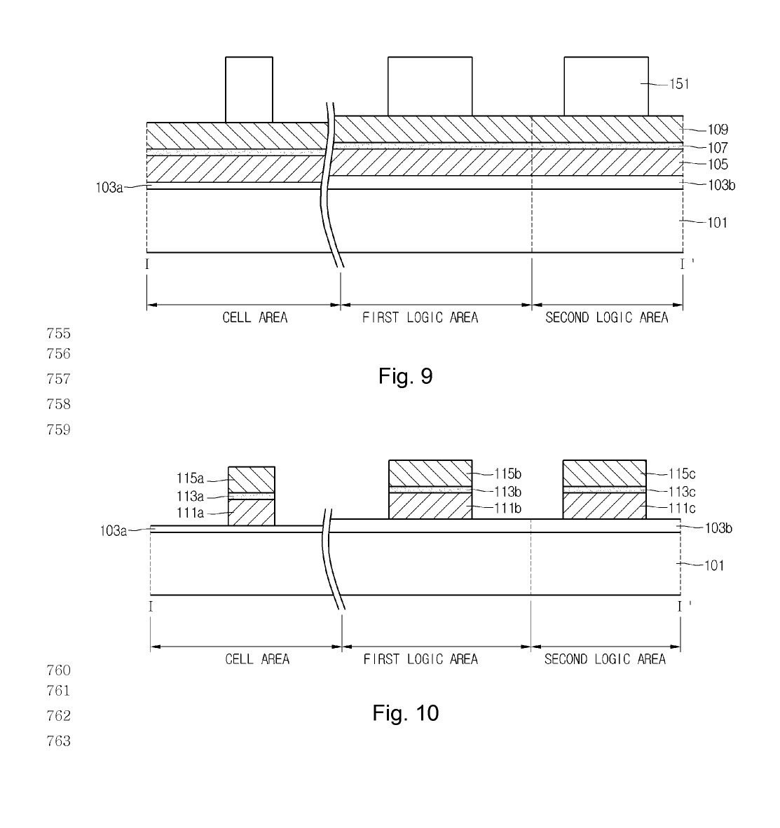

As shown in FIG. 9, a first photoresist pattern 151 is formed on the second polysilicon layer 109.

As shown in FIG. 10, the second polysilicon layer 109, the ONO layer 107 and the first polysilicon layer 105 are etched using the first photoresist pattern 151 as a mask. After that, the first photoresist pattern 151 is removed from the semiconductor substrate 101 (generally by ashing).

The first polysilicon layer 105, the ONO layer 107 and the second polysilicon layer 109 in the cell area are patterned to form the gate stack including the floating gate pattern 111a, the ONO pattern 113a and the control gate pattern 115a. The first polysilicon layer 105, the ONO layer 107 and the second polysilicon layer 109 in the first logic area are patterned to form the first gate pattern 111b, the first dummy ONO pattern 113b and the first dummy gate pattern 115b. The first polysilicon layer 105, the ONO layer 107 and the second polysilicon layer 109 in the second logic area are patterned to form the second gate pattern 111c, the second dummy ONO pattern 113c and the second dummy gate pattern 115c.

According to exemplary embodiments, the gates can be formed by sequentially depositing and patterning the first polysilicon layer 105, the ONO layer 107 and the second polysilicon layer 109 without separately performing a photo process. Accordingly, the manufacturing process can be simplified and defects caused by particles generated during a second etching process (e.g., to form the polysilicon layer in either of the logic areas or the cell area) can be prevented.

In addition, after the ONO layer has been formed, the second polysilicon layer 109 is formed on the ONO layer 107 without instantly performing a photolithography process and an etching process after forming the ONO layer, so that the exposure time of the ONO layer 107 to chemical solution(s) and/or air is minimized, thereby preventing loss of an upper part of the oxide layer of the ONO layer 107 and preventing degradation of data retention reliability due to formation of trap sites, which can be generated on a surface of the upper part of the oxide layer. Accordingly, the reliability of the flash memory device can be effectively improved.

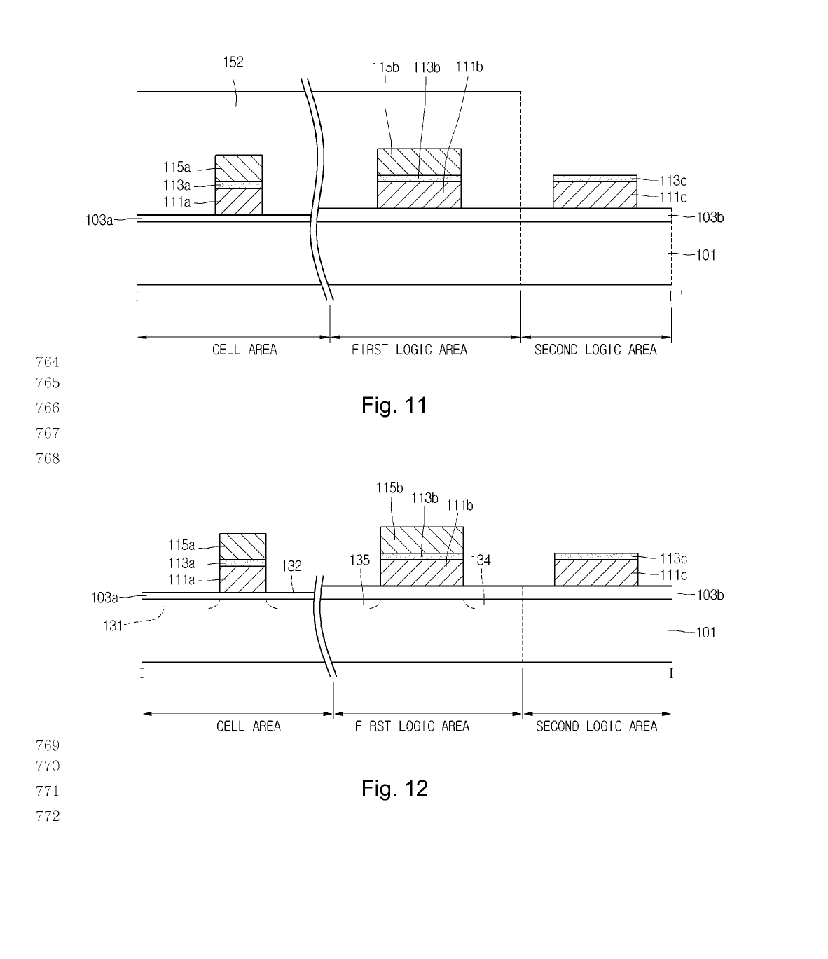

As shown in FIG. 11, an opening process for the second logic area is performed. A second photoresist pattern 152 is formed on the semiconductor substrate 101 such that the cell area and the first logic area are covered with the second photoresist pattern 152. The second photoresist pattern 152 exposes the second gate pattern 111c, the second dummy ONO pattern 113c and the second dummy gate pattern 115c of the second logic area. Then, the exposed second dummy gate pattern 115c is etched, so that the second dummy ONO pattern 113c is exposed.

The second logic area serves as an area for applying a gate voltage to the second gate pattern 111c through a gate contact. The second gate pattern 111c is connected to the first gate pattern 111b to transfer the applied voltage.

The second photoresist pattern 152 exposes a predetermined area of the second logic area such that an active area of the semiconductor substrate 101 can be prevented from being damaged during the etching process of the second polysilicon layer 109. Then, the second photoresist pattern 152 is removed.

Since the pattern of the second logic area has a critical dimension margin larger than that of the pattern of the cell area, the cost for the corresponding mask can be lowered. Accordingly, it is preferred in terms of the manufacturing cost to perform a mask (e.g., photolithography) process for removing the dummy gate pattern in the second logic area after simultaneously forming the gate patterns (e.g., by performing photolithography and etching processes on to the first polysilicon layer 105, the ONO layer 107 and the second polysilicon layer 109), without separately forming the gate patterns in the logic area and the cell area. In addition, since the mask used for removing the dummy gate pattern has a relatively large pattern size, the mask is easily aligned, so that pattern defects can be reduced.

As shown in FIG. 12, lightly doped first conductivity-type impurities are implanted using the gate stack in the cell area as an ion implantation mask, so that the first lightly doped ion implantation areas 131 and 132 are formed. Then, lightly doped first conductivity-type impurities are implanted using the first gate pattern 111b, the first dummy ONO pattern 113b and the first dummy gate pattern 115b in the logic area as an ion implantation mask, so that the second lightly doped ion implantation areas 133 and 134 are formed. The first impurities may include a ‘p type’ impurity or an ‘n type’ impurity.

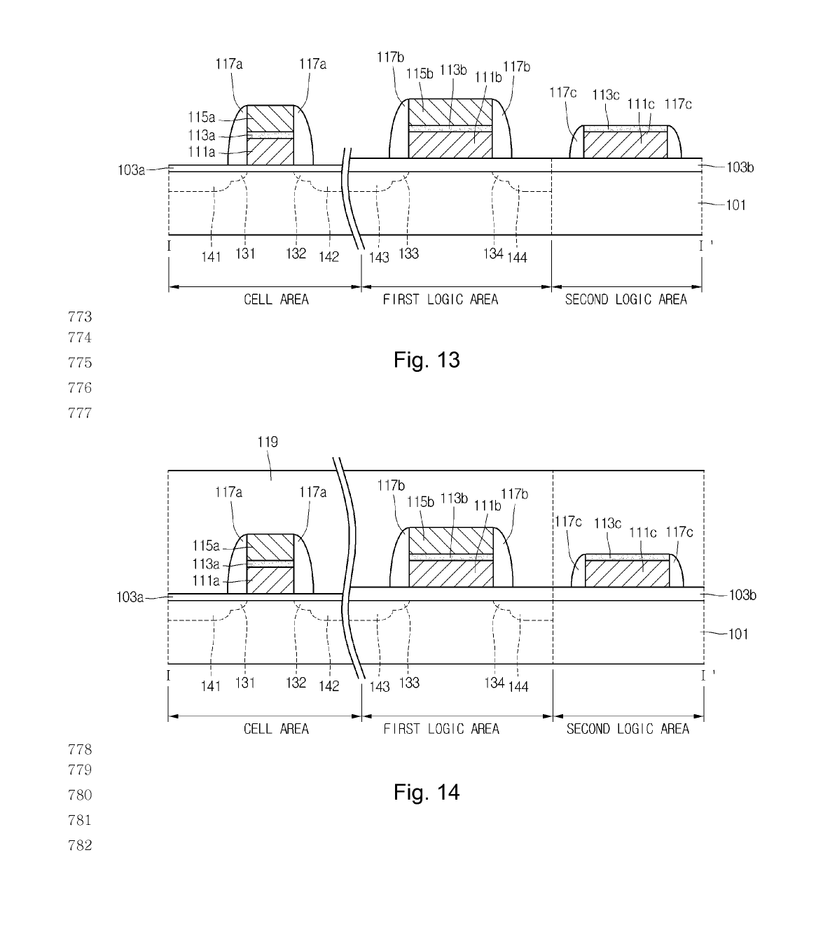

Gate spacer material is formed on the entire surface of the semiconductor substrate 101, and then, as shown in FIG. 13, the gate spacer material is subject to an anisotropic etching process, thereby forming the first to third gate spacers 117a, 117b and 117c.

As shown in FIG. 13, heavily doped first conductivity-type impurity regions are implanted into the semiconductor substrate 101 using the gate stack and the first gate spacer 117a of the cell area as a mask, so that the source area 142 and the drain area 141 are formed. The first impurities may include a ‘p type’ impurity or an ‘n type’ impurity. Simultaneously or separately, heavily doped first conductivity-type impurity regions are implanted into the semiconductor substrate 101 using the first gate pattern 111b and the second gate spacer 117b of the first logic area as a mask, so that the source area 143 and the drain area 144 are formed. The heavily doped first conductivity-type impurities can be implanted into the second logic area or not.

In the first logic area, the first dummy ONO pattern 113b and the first dummy gate pattern 115b are formed on the first gate pattern 111b in the first logic area, so that the dummy pattern is formed on the first gate pattern 111b which substantially serves as a gate electrode. The gate pattern of the logic area according to various embodiments has a thickness thicker than that of conventional gate pattern, and the thick gate pattern enables the impurities to be deeply implanted into the semiconductor substrate 101 during a junction implantation. That is, since a deep junction implantation of the high voltage driving transistor is ensured on the first logic area, a breakdown voltage can be increased and an off-current can be decreased, even if an additional thermal diffusion process is not performed, so that the electrical (e.g., switching) characteristic(s) of the device can be improved.

As shown in FIG. 14, the interlayer dielectric layer 119 is formed on the entire surface of the semiconductor substrate 101. The interlayer dielectric layer 119 includes at least one of a BPSG (borophosphosilicate glass), a USG (undoped silicate glass), a TEOS (tetraethylorthosilicate-based glass) and an FSG (fluorinated silica glass). An upper surface of the interlayer dielectric layer 119 is flat. This is because the gate stack of the cell area has a height similar or substantially identical to that of the gate pattern of the logic area.

The gate stack is formed by sequentially stacking the floating gate pattern 111a, the ONO pattern 113a and the control gate pattern 115a. The gate pattern of the logic area includes the first gate pattern 111b, the first dummy ONO pattern 113b and the first dummy gate pattern 115b. Accordingly, the gap-fill uniformity and the planarity of the interlayer dielectric layer 119 formed on the cell area and the logic area are improved.

After the interlayer dielectric layer 119 has been formed on the semiconductor substrate 101 with a sufficient thickness, a CMP (Chemical Mechanical Polishing) process is performed to polish an upper part of the interlayer dielectric layer 119. Since the interlayer dielectric layer 119 according to exemplary embodiments has a substantially planar structure, a CMP margin and CMP uniformity can be improved.

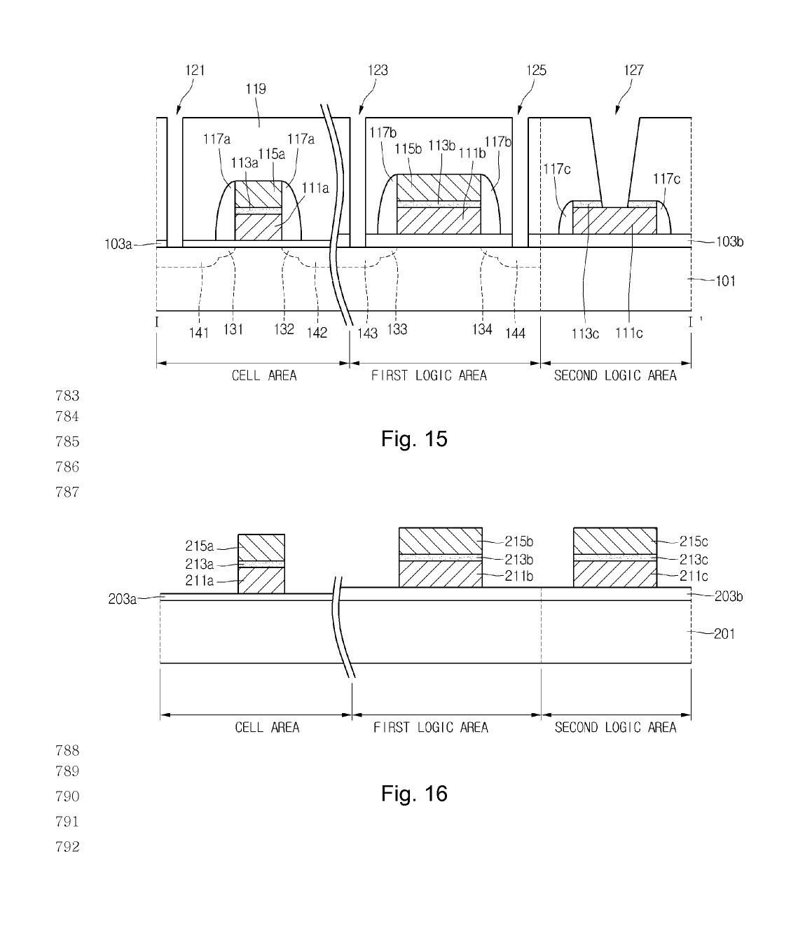

As shown in FIG. 15, the interlayer dielectric layer 119 is selectively etched to form the contact holes 121, 123, 125 and 127. The interlayer dielectric layer 119 includes the first contact hole 121 through which a portion of the drain area 141 of the cell area is exposed, and the second and third contact holes 123 and 125 through which the source and drain areas 143 and 144 of the first logic area are exposed, respectively. In addition, the interlayer dielectric layer 119 includes the fourth contact hole 127 through which an upper part of the second gate pattern 111c of the second logic area is exposed.

After that, conductive material such as tungsten is formed in the contact holes 121, 122, 125 and 127 to form a contact electrode. In the subsequent processing, a metal interconnection, which is electrically connected to the contact electrode, is formed on the interlayer dielectric layer 119.

The exemplary flash memory device and the exemplary manufacturing process for the flash memory device can be simplified and the manufacturing cost can be reduced. Also, a defect rate of the device can be lowered and reliability of the device in the cell area can be improved. Additionally, electrical characteristics of the flash memory device can be improved.

FIGS. 16 to 21 are sectional views sequentially showing a second exemplary process of manufacturing a flash memory device.

In the following description, the process steps that are identical to the first exemplary process will be omitted in order to avoid redundancy.

As shown in FIG. 16, the first polysilicon layer, the ONO layer and the second polysilicon layer in the cell area are patterned, thereby forming a gate stack including a floating gate pattern 211a, an ONO pattern 213a and a control gate pattern 215a. The first polysilicon layer, the ONO layer and the second polysilicon layer in the first logic area are also patterned, preferably simultaneously, thereby forming a first gate pattern 211b, a first dummy ONO pattern 213b and a first dummy gate pattern 215b.

The first polysilicon layer, the ONO layer and the second polysilicon layer in the second logic area are also patterned, preferably simultaneously with the same layers in the first logic area and the cell area, thereby forming a second gate pattern 211c, a second dummy ONO pattern 213c and a second dummy gate pattern 215c.

According to the exemplary process, the gates can be formed by sequentially depositing and patterning the first polysilicon layer 105, the ONO layer 107 and the second polysilicon layer 109 without separately performing a photo process. Accordingly, the manufacturing process can be simplified, and defects caused by particles generated during a second etching process of the polysilicon layer can be prevented.

In addition, the second polysilicon layer is formed on the ONO layer without instantly performing photo and etching processes after forming the ONO layer, so that the exposure time of the ONO layer to chemical solution(s) or air is minimized, thereby preventing loss of an upper part of the oxide layer of the ONO layer and preventing degradation of data retention reliability due to trap sites that may be generated on a surface of the upper oxide layer. Accordingly, the reliability of the flash memory device can be effectively improved.

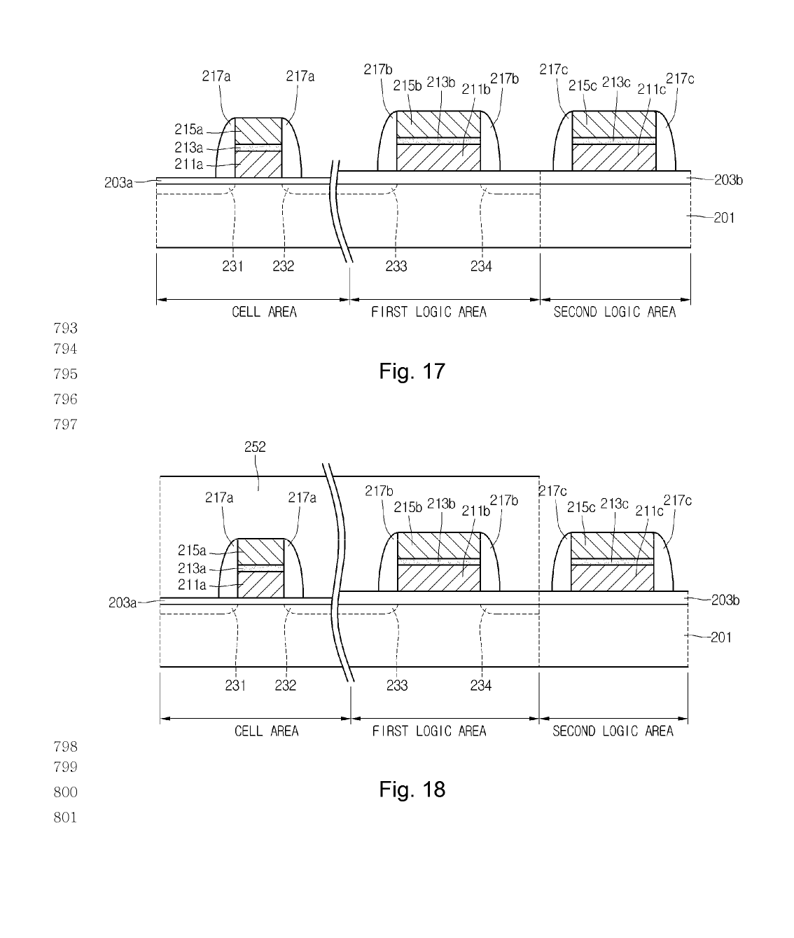

As shown in FIG. 17, lightly doped first conductivity-type impurity regions are implanted using the gate stack of the cell area as an ion implantation mask, so that first lightly doped ion implantation areas 231 and 232 are formed. Then, lightly doped first conductivity-type impurity regions are implanted using the first gate pattern 211b, the first dummy ONO pattern 213b and the first dummy gate pattern 215b as an ion implantation mask, so that second lightly doped ion implantation areas 233 and 234 are formed. These implantation steps may be performed separately or simultaneously. The first impurities may include a ‘p type’ impurity or an ‘n type’ impurity.

After that, gate spacer material is formed on the entire surface of the semiconductor substrate 201, and then the gate spacer material is subject to an anisotropic etching, thereby forming first to third gate spacers 217a, 217b and 217c. The first gate spacer 217a covers a portion of the semiconductor substrate 201 corresponding to sides of the gate stack while covering the sides of the gate stack. The second gate spacer 217b covers sides of the first gate pattern 211b, the first dummy ONO pattern 213b and the first dummy gate pattern 215b. The third gate spacer 217c covers sides of the second gate pattern 211c, the second dummy ONO pattern 213c and the second dummy gate pattern 215c. The first to third spacers 217a, 217b and 217c may have a height and shape substantially identical to each other.

As shown in FIG. 18, an opening process for the second logic area is performed. A third photoresist pattern 252 is formed on the semiconductor substrate 201 such that the cell area and the first logic area are covered with the third photoresist pattern 252. The third photoresist pattern 252 exposes the second gate pattern 211c, the second dummy ONO pattern 213c and the second dummy gate pattern 215c of the second logic area. The exposed second dummy gate pattern 215c is etched, so that the second dummy ONO pattern 213c is exposed.

The third gate spacer 217c extends upward beyond the second dummy ONO pattern 213c while covering the sides of the second gate pattern 211c and the second dummy ONO pattern 213c. The third gate spacer 217 prevents a second gate pattern 211c, in which a side of the second gate pattern 211c is exposed, from being etched when the second dummy gate pattern 215c is etched, so that gate pattern defects can be prevented.

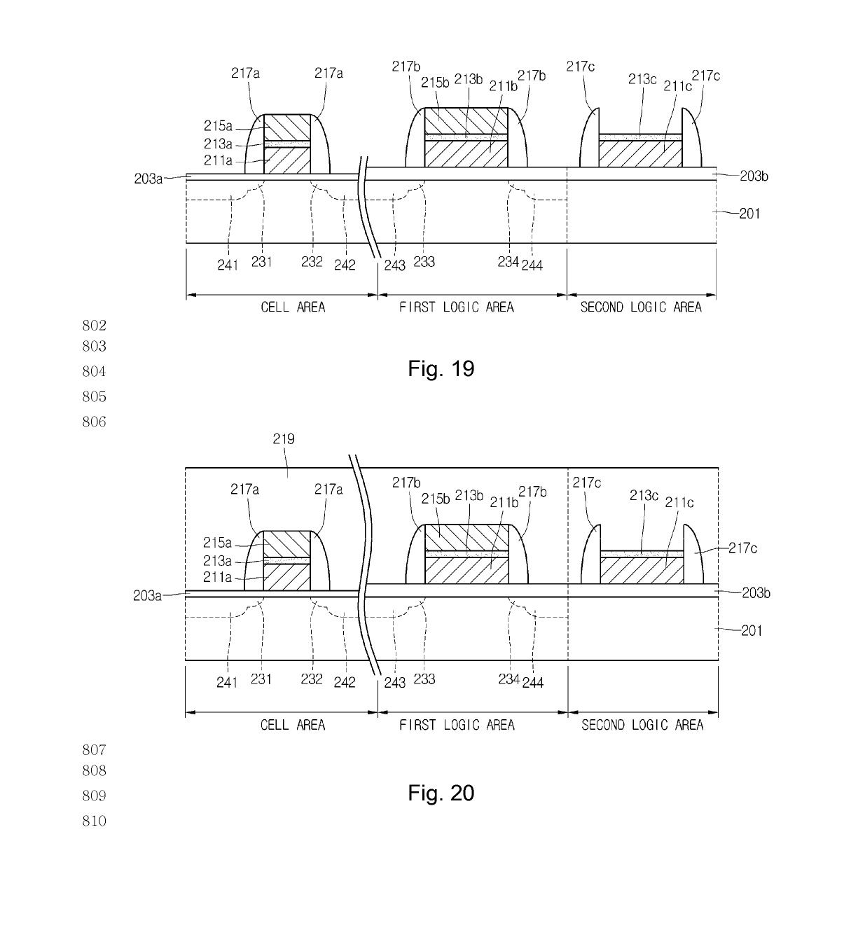

Referring to FIG. 19, first conductivity-type impurities are implanted (or heavily doped) into the semiconductor substrate 201 using the gate stack and the first gate spacer 217a of the cell area as a mask, so that a source area 242 and a drain area 241 are formed. The first impurities may include a ‘p type’ impurity or an ‘n type’ impurity.

Heavily doped first conductivity-type impurities are also implanted into the semiconductor substrate 201 using the first gate pattern 211b and the second gate spacer 217b of the first logic area as a mask, so that a source area 243 and a drain area 244 are formed, separately from or simultaneously with the cell area.

As shown in FIG. 20, an interlayer dielectric layer 219 is formed on the entire surface of the semiconductor substrate 201. An upper surface of the interlayer dielectric layer 219 maybe planar. This is because the gate stack of the cell area has a height substantially identical to that of the gate pattern of the logic area. Accordingly, the gap-fill uniformity and the planarity of the interlayer dielectric layer 219 formed on the cell area and the logic area are improved.

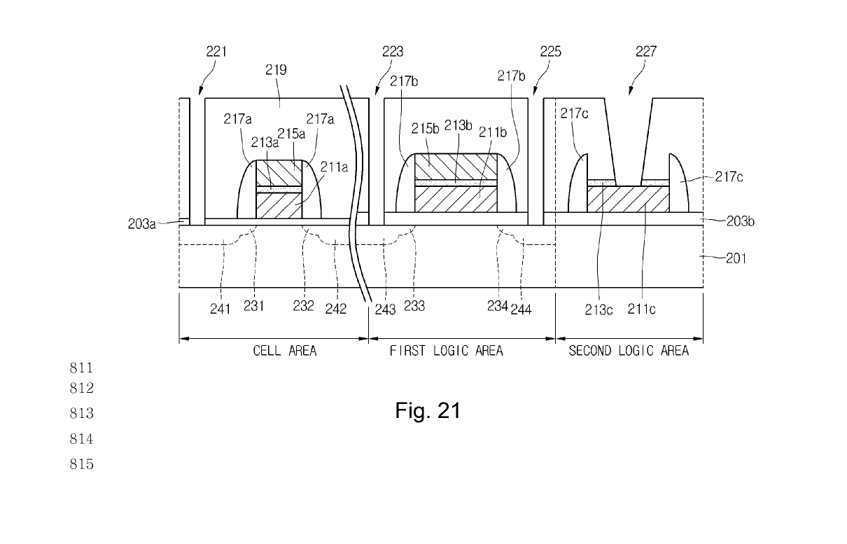

As shown in FIG. 21, the interlayer dielectric layer 219 is selectively etched to form contact holes 221, 223, 225 and 227. Even if the fourth contact hole 227 is misaligned in the second logic area, a contact hole margin can be ensured by the third spacer 217c formed at the sides of the second gate pattern 211c.

Then, a contact electrode is formed by forming conductive material in the contact holes 221, 223, 225 and 227. In subsequent processing, a metal interconnection, which is electrically connected to the contact electrode, can be formed on the interlayer dielectric layer 219.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What si claimed is:

1. A flash memory device comprising:
a first gate pattern and a second gate pattern on a semiconductor substrate and connected to each other;
a first dummy insulating layer pattern covering the first gate pattern;
a first dummy gate pattern covering the first dummy insulating layer pattern; and
a dielectric layer that covers the first dummy gate pattern and the second gate pattern and has a contact hole exposing a portion of the second gate pattern.

2. The flash memory device as claimed in claim 1, further comprising:
a first spacer that covers sides of the first gate pattern, the first dummy insulating layer pattern and the first dummy gate pattern; and
a second spacer, connected to the first spacer, covering a side of the second gate pattern, and having a height lower than that of the first spacer.

3. The flash memory device as claimed in claim 1, further comprising:
a first spacer that covers sides of the first gate pattern, the first dummy insulating layer pattern and the first dummy gate pattern; and
a second spacer, connected to the first spacer, covering a side of the second gate pattern, and extending beyond the second gate pattern by a predetermined length or height.

4. The flash memory device as claimed in claim 1, comprising a second dummy insulating layer pattern on the second gate pattern.

5. The flash memory device as claimed in claim 1, wherein the first gate pattern is integral with the first gate pattern.

6. The flash memory device as claimed in claim 1, wherein the first dummy insulating pattern and the first dummy gate pattern expose the second gate pattern.

7. The flash memory device as claimed in claim 1, wherein an exposed upper surface of the second gate pattern makes contact with the dielectric layer.

8. A flash memory device having a cell area and a logic area, comprising:
a gate stack including a floating gate pattern, an insulating layer pattern and a control gate pattern on a semiconductor substrate in the cell area;
a first gate spacer covering a side of the gate stack;
a first gate pattern and a second gate pattern connected to each other, on the semiconductor substrate in the logic area;
a first dummy insulating layer pattern covering the first gate pattern;
a first dummy gate pattern covering the first dummy insulating layer pattern;
a second gate spacer which covers sides of the first gate pattern, the first dummy insulating layer pattern and the first dummy gate pattern;
a third gate spacer connected to the second gate spacer and covering a side of the second gate pattern; and
a dielectric layer that has a contact hole exposing a portion of the second gate pattern.

9. The flash memory device as claimed in claim 8, wherein the first spacer has a height identical to that of the second gate spacer, and the third gate spacer has a height smaller than that of the second gate spacer.

10. The flash memory device as claimed in claim 8, wherein the first gate pattern is integral with the second gate pattern.

11. The flash memory device as claimed in claim 8, wherein the third gate spacer extends beyond the second gate pattern by a predetermined length or height.

12. The flash memory device as claimed in claim 8, further comprising a second dummy insulating layer pattern on the second gate pattern.

13. The flash memory device as claimed in claim 8, wherein the semiconductor substrates includes a source area and a drain area on opposite sides of the first gate pattern, and the dielectric layer includes additional contact holes partially exposing the source area and the drain area.

14. A method of manufacturing a flash memory device, the method comprising the steps of:
sequentially stacking a first polysilicon layer, an insulating layer and a second polysilicon layer on a semiconductor substrate having a cell area and a logic area;
patterning the first polysilicon layer, the insulating layer and the second polysilicon layer to form a first gate stack in the cell area and a second gate stack in the logic area;
forming a photoresist pattern covering the first gate stack and a portion of the second gate stack;
removing the second polysilicon layer of the second gate stack exposed by the photoresist pattern;
removing the photoresist pattern and then forming a spacer on sides of the first gate stack and the second gate stack;
forming a dielectric layer covering the first gate stack and the second gate stack; and
exposing a portion of the second gate stack by selectively etching the dielectric layer.

15. The method as claimed in claim 14, wherein the step of forming the spacer comprises the steps of:
depositing a spacer material layer on an entire surface of the semiconductor substrate; and
anisotropically etching the spacer material layer to form the first spacer and the second spacer.

16. The method as claimed in claim 15, wherein the second spacer has a variable height depending on a position thereof.

17. The method as claimed in claim 14, further comprising the steps of:
forming an oxide layer by heating the semiconductor substrate in an oxygen atmosphere;
forming an oxide layer pattern in the logic area by patterning the oxide layer; and
forming a first gate insulating layer on the cell area and a second gate insulating layer, which has a thickness thicker than a thickness of the first insulating layer, in the logic area by heat-treating the semiconductor substrate, before stacking the first polysilicon layer, the insulating layer and the second polysilicon layer on the semiconductor substrate.

18. A method of manufacturing a flash memory device, the method comprising the steps of:
sequentially stacking a first polysilicon layer, an insulating layer and a second polysilicon layer on a semiconductor substrate;
patterning the first polysilicon layer, the insulating layer and the second polysilicon layer to form a first gate stack and a second gate stack, respectively:
forming a first spacer and a second spacer that cover sides of the first gate stack and the second gate stack, respectively;
forming a photoresist pattern covering the first gate stack and a portion of the second gate stack;
removing the second polysilicon layer of the second gate stack exposed by the photoresist pattern;
removing the photoresist pattern and forming a dielectric layer covering the first gate stack and the second gate stack; and
exposing a portion of the second gate stack by selectively etching the dielectric layer.

19. The method as claimed in claim 18, wherein the step of forming the first and second spacers at the sides of the first gate stack and the second gate stack comprises the steps of:
depositing a spacer material layer on an entire surface of the semiconductor substrate; and
anisotropically etching the spacer material layer to form a first spacer covering the side of the first gate stack and a second spacer covering the side of the second gate stack.

20. The method as clamed in claim 19, wherein the first spacer has a height identical to a height of the second spacer.
